(19) United States
(12) Patent Application Publication
(10) Pub. No.: US 2025/0016230 A1
(43) Pub. Date: Jan. 9, 2025

(54) DISTRIBUTED COMPRESSIVE SENSING OF MULTI-DOMAIN SPARSE SIGNALS IN DISTRIBUTED EDGE SYSTEMS

(71) Applicant: VMware, Inc., Palo Alto, CA (US)

(72) Inventor: Hoda DEHGHAN, Ottawa (CA)

(21) Appl. No.: 18/348,145

(22) Filed: Jul. 6, 2023

(51) Int. Cl. H04L 67/12; G16Y 10/75

(52) U.S. Cl. CPC H04L 67/12; G16Y 10/75; H03H 2021/0036

(57) ABSTRACT

An example receiver in a distributed edge system includes sensors configured to receive radio frequency (RF) signals from a channel in an environment. The sensors include front-end circuits configured to convert the RF signals into mixed signals at baseband having a discrete-time basis. Each of the mixed signals includes a mixture of source signals, which are compressively sampled and transmitted by sources in the distributed edge system over the channel. The receiver includes a processor, coupled to the sensors, configured to use measurements of the mixed signals with an implementation of convolutive blind source separation (CBSS) in multiple domains to separate estimated source signals from the mixed signals and determine estimated channel coefficients for the channels. The processor is configured to send, to the sources, information to adjust sampling rates in response to a relation between the measurements, the estimated source signals, and the estimated channel coefficients.

### BACKGROUND

In distributed edge systems, such as Internet-of-Things (IoT) applications, sending under-sampled versions of observed signals is needed to overcome delay and bandwidth limitations. For most IoT applications, the channel between sources and sensors is unknown, which leads to using blind source separation at the sensors.

Some sources are sparse in concatenation of multiple domains. Such sources have different morphologies and each part of the signal is sparse in a specific domain (e.g., time domain or frequency domain). Morphological component analysis (MCA) can estimate these types of sources. Some other sources are sparse in multiple domains (e.g., both the time domain and the frequency domain). Such sources are different from the sources with different morphologies. For the multiple domain, sparse signal category, the whole signal is sparse in multiple domains. In contrast, for the category of sources with different morphologies, each part of a signal is sparse in a specific domain.

Compressive sensing (CS) is a widespread signal processing technique that can recover an unknown sparse signal with high probability from a small set of linear projections (measurements) under certain conditions. The number of required measurements to exact recovery is related to the dimension of the signal and its sparsity. Using CS for data transfer and information sharing has gained a lot of interest because low-latency communication for large-scale sensing scenarios can be achieved only by significantly reducing the data to transmit. Thus, CS can be applied to reduce transmission time, without sacrificing the inference accuracy. For some applications, the sparsity of the data is known. But for other applications, learning the optimal or sub-optimal dictionaries to transform the data to the domain of sparsity is the main challenge. In both known and unknown dictionary cases, existing CS methods are designed for centralized sensing and reconstruction. However, in distributed edge applications, such as IoT application, it is desirable to use distributed CS methods to scale down the total transmitted payload by applying multi-domain compression.

### SUMMARY

In an embodiment, a receiver in a distributed edge system comprises: sensors configured to receive radio frequency (RF) signals from a channel in an environment. The sensors include front-end circuits configured to convert the RF signals into mixed signals at baseband having a discrete-time basis. Each of the mixed signals comprises a mixture of source signals, which are compressively sampled and transmitted by sources in the distributed edge system over the channel. The receiver includes a processor, coupled to the sensors, configured to use measurements of the mixed signals with an implementation of convolutive blind source separation (CBSS) in multiple domains to separate estimated source signals from the mixed signals and determine estimated channel coefficients for the channels. The processor is configured to send, to the sources, information to adjust sampling rates in response to a relation between the measurements, the estimated source signals, and the estimated channel coefficients.

In another embodiment, a method of receiving in a distributed edge system, the distributed edge system comprising sources that compressively sample and transmit source signals over a channel to a receiver, is described. The method includes receiving, at the receiver, radio frequency (RF) signals from the channel in an environment. The method includes converting, using front-end circuits of the receiver, the RF signals into mixed signals at baseband having a discrete-time basis, each of the mixed signals comprising a mixture of the source signals. The method includes executing, at a processor of the receiver, an implementation of convolutive blind source separation (CBSS) in multiple domains using measurements of the mixed signals as input to separate estimated source signals from the mixed signals and determine estimated channel coefficients for the channels. The method includes sending, from the receiver to the sources, information to adjust sampling rates in response to a relation between the measurements, the estimated source signals, and the estimated channel coefficients.

In another embodiment, a distributed edge system comprises sources disposed in an environment. The sources are configured to compressively sample and transmit source signals. The system includes a receiver disposed in the environment. The receiver includes sensors configured to receive radio frequency (RF) signals from a channel in the environment, the sensors including front-end circuits configured to convert the RF signals into mixed signals at baseband having a discrete-time basis, each of the mixed signals comprising a mixture of the source signals. The receiver includes a processor, coupled to the sensors, configured to use measurements of the mixed signals with an implementation of convolutive blind source separation (CBSS) in multiple domains to separate estimated source signals from the mixed signals and determine estimated channel coefficients for the channels. The processor is configured to send, to the sources, information to adjust sampling rates in response to a relation between the measurements, the estimated source signals, and the estimated channel coefficients.

Further embodiments include a non-transitory computer-readable storage medium comprising instructions that cause a computer system to carry out the above method, as well as a computer system configured to carry out the above method.

### BRIEF DESCRIPTION OF THE DRAWINGS

FIG. 1 is a block diagram depicting a distributed edge system according to embodiments.

FIG. 2 is a block diagram depicting logical operation of a processor in a receiver of a distributed edge system according to embodiments.

FIG. 3 is a block diagram depicting logical operation of a processor in feeding back information to sources and front-ends in a distributed edge system according to embodiments.

FIG. 4 is a flow diagram depicting a method of estimating source signals and channel coefficients using CBSS according to embodiments.

FIGS. 5A-5B depict a flow diagram showing a method of controlling parameters in a distributed edge system according to embodiments.

FIGS. 6A-6B depict a flow diagram showing a method of multi-domain adaptive thresholding (MDAT) according to embodiments.

FIGS. 7A-7B depict a flow diagram showing a method of multi-domain blind adaptive message passing (MDBAMP) according to embodiments.

### DETAILED DESCRIPTION

Distributed compressive sensing of multi-domain sparse signals in distributed edge systems is described. In embodiments, a distributed edge system, such as an Internet-of-Things (IoT) system, comprises a wireless system having a plurality of sources and a receiver. The receiver includes a plurality of sensors coupled to a processor. The sources observe signals in an environment (e.g., a residential environment, commercial environment, industrial environment, etc.). The environment signals can be generated by various devices in the environment. A source observes an environment signal by sampling the signal using a sampling rate to generate a discrete-time source signal. The sources collectively generate a plurality of discrete-time source signals in this manner (“source signals”). A source transmits its source signal into an air channel by modulating a radio frequency (RF) carrier with its source signal and transmitting the resulting RF signal. The sources collectively transmit the source signals into the channel such that, at each sensor of the receiver, the received signal is a linear mixture of the source signals. That is, each sensor of the receiver receives from the channel and generates a discrete-time mixed signal comprising a linear combination of the source signals. The sensors obtain the mixed signals by demodulating the RF signals received from the channel to baseband signals. The processor receives the mixed signals from the sensors. At the receiver, the source signals and the channel are unknown. The processor uses convolutive blind source separation (CBSS) using the mixed signals as input to estimate both the source signals and the channel.

The system uses distributed compressive sensing to exploit both intra- and inter-signal correlation structures. Compressive sensing (also referred to as compressive sampling or sparse sampling) relies on few samples being sufficient to reconstruct an observed signal that is sparse in some basis or bases (i.e., far fewer samples than required by the Nyquist-Shannon theorem). Traditional CS exploits intra-signal correlations at a single sensor. In a multi-sensor, multi-source environment (i.e., multiple-input, multiple output (MIMO) environment), measurements can be obtained from each source signal separately and estimated source signals recovered separately. However, in embodiments, the receiver combines measurements from all sensors to exploit both intra- and inter-signal correlations and recover estimates of the source signals concurrently using CBSS. Such a CS implementation is referred to herein as distributed compressing sensing (DCS).

In embodiments, the processor uses CBSS implementations that take advantage of multi-domain sparsity in the source signals. Using the source signal sparse representations in all sparse domains helps in estimating the source signals more precisely with fewer number of measurements. In an embodiment, the processor uses a multi-domain adaptive thresholding (MDAT) implementation of CBSS for both under-determined and over-determined cases. In an under-determined case, there are fewer mixed signal measurements than samples in the source signals to be estimated. In an over-determined case, there are more mixed signal measurements than samples in the source signals to be estimated. In another embodiment, the processor uses a multi-domain blind approximate messaging passing (MDBAMP) implementation of CBSS for under-determined cases. Both the MDAT and MDBAMP implementations outperform corresponding ones that use only a single domain of sparsity in the source signals.

In embodiments, the receiver feeds back information to the sources, the sensors, or both based on the estimated source signals and estimated channel coefficients. The processor can determine the sparsity of the estimated source signals across domains, identify over-determined and under-determined conditions, and send information to the sources for adjusting the sampling rates. The processor can feed back estimated channel coefficients to the sensors to adapt the receiving process to the changing channels. This can improve the accuracy of the mixed signals. These and further aspects of the compressive sensing techniques are described below with respect to the drawings.

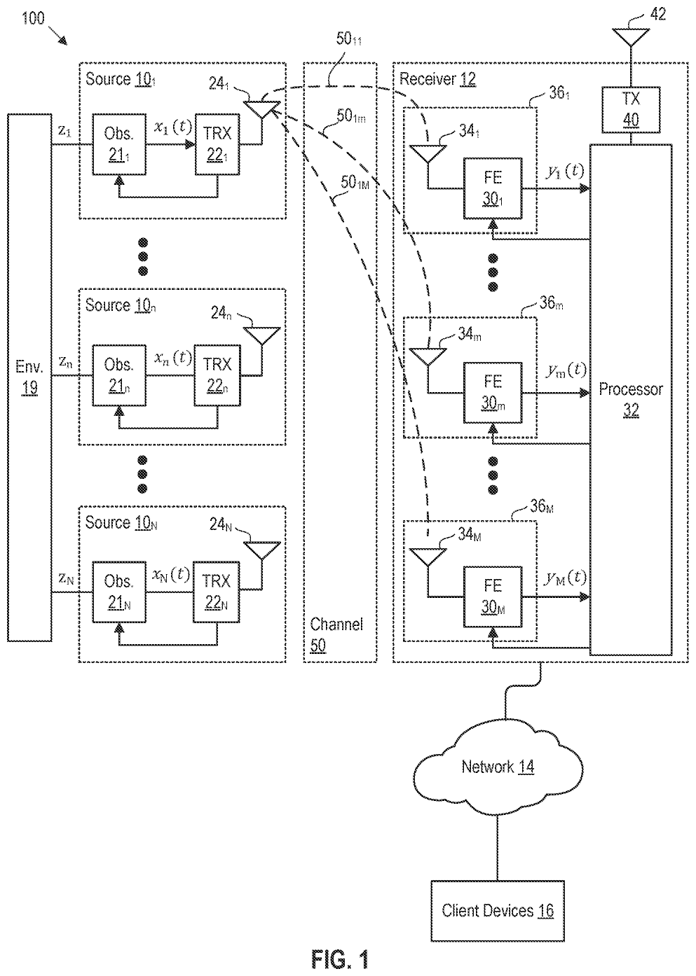

FIG. 1 is a block diagram depicting a distributed edge system 100 according to embodiments. Distributed edge system 100 comprises a plurality of sources 10, for example, sources 10₁ . . . 10_{N}, where N is an integer greater than one. A source 10ₙ refers to an n-th source n∈{1, 2, . . . , N}. Each source 10 includes an observer circuit (“observer 21”), a transceiver 22, and an antenna 24. Thus, sources 10₁ . . . 10_{N} respectively include observers 21₁ . . . 21_{N}, transceivers 22₁ . . . 22_{N}, and antennae 24₁ . . . 24_{N}. Source 10ₙ includes n-th device 20ₙ, n-th sampler 21ₙ, n-th transceiver 22ₙ, and n-th antenna 24ₙ.

Each observer 21 observes a signal generated in environment 19 (“environment signal”). The environment signals can be generated by various devices in environment 19. For example, in a residential environment, the devices can include appliances, doorbell cameras, smart locks, thermostats, smart light bulbs, smart electrical outlets and light switches, and the like. Environment 19 generates N environment signals z₁ . . . z_{N}. Environment signals can be continuous-time signals or discrete-time signals. Observers 21₁ . . . 21_{N} sample environment signals z₁ . . . z_{N}, respectively, at selected sampling rates. In embodiments, the sampling rates of observers 21 are selected based on feedback information from receiver 12, as discussed further below. Observers 21 output source signals x(t)=(x₁(t), . . . , x_{N}(t)), where t is a discrete time index. The n-th observer 21ₙ samples the nth environment signal zₙ to generate the nth source signal xₙ(t). As described further below, in embodiments, observers 21 sample the environment signals in a manner that the resulting source signals are sparse in multiple domains (e.g., in the time domain and the frequency domain). A signal is sparse in a domain when some proportion of its samples are zero when projected onto that domain (e.g., half or more than half the samples are zero).

Transceivers 22 transmit the source signals in a channel 50 comprising air. A transceiver 22 modulates an RF carrier with the source signal output by an observer 21 to generate an RF signal and radiates the RF signal from an antenna 24. Thus, sources 10₁ . . . 10_{N} transmit N RF signals into channel 50.

Distributed edge system 100 includes a receiver 12. Receiver 12 includes a plurality of sensors 34, for example, sensors 34₁ . . . 34_{M}, where M is an integer greater than one. In embodiments, M<N. A sensor 34ₘ refers to an m-th sensor m∈{1, 2, . . . , M}. Each sensor 36 includes an antenna 34 and a front-end (FE) 30. Thus, sensors 34₁ . . . 34_{M} respectively include antennae 34₁ . . . 34_{M} and FEs 30₁ . . . 30_{M}. Sensor 36ₘ includes an m-th antenna 34ₘ and an m-th FE 30ₘ. FEs 30₁ . . . 30_{M} each receive a linear combination of the source signals x(t) from channel 50 and generate mixed signals y(t)=(y₁(t), . . . , y_{M}(t)), where t is the discrete time index. An FE 30 receives an RF signal from channel 50 through an antenna 34, demodulates the RF signal to generate a baseband signal, and outputs a discrete-time mixed signal. There is a path in channel 50 between a given source 10 and each sensor 36. Thus, there path 50₁₁, between source 10₁ and sensor 36₁; a path 50₁ₘ between source 10₁ and sensor 36ₘ; and a path 50_{1M} between source 10₁ and sensor 36_{M}. In general, there is a path 50ₘₙ between source 10ₙ and sensor 36ₘ for all n, m where 1≤n≤N and 1≤m≤M. Paths other than 50₁₁, 50₁ₘ, and 50_{1M} are omitted from FIG. 1 for clarity. Each path in channel 50 can be considered a channel between a source and a sensor modeled by a finite impulse response (FIR) filter having a set of coefficients (“channel coefficients”).

Receiver 12 includes a processor 32 that receives the mixed signals y(t) from sensors 36. In embodiments, processor 32 can feedback estimated channel coefficients to FEs 30. FEs 30 can use the estimated channel coefficients to adapt receiving RF signals from channel 50 as channel 50 changes. Receiver 12 can include a transmitter 40 (e.g., receiver 12 and transmitter 40 can be a transceiver) coupled to an antenna 42. Processor 32 can send information to sources 10 to adjust sampling rates of observers 21 by broadcasting the information from transmitter 40 to be received by transceivers 22. Receiver 12 can be connected to a network 14 for communication with client devices 16.

Distributed edge system 100 can be modeled using a convolutive mixing model. In this model, there are M sensors. Each of the M sensors receives a convolutive mixture of N source signals x(t)=(x₁(t), . . . , x_{N}(t)), where t is the discrete time index. The received signals (“mixed signals”) are denoted by y(t)=(y₁(t), . . . , y_{M}(t)). The relationship between the m-th mixed signal and all the source signals can be written as:

$${y}_{m} ( t ) = {\sum }_{n = 1}^{N} {\sum }_{t = 0}^{L} {a}_{mn} ( l ) {x}_{n} ( t - l ) + w ( t ) , \qquad ( 1 )$$

where aₘₙ(l), l=0, . . . , L are FIR filter coefficients between the n-th source signal and the m-th sensor and L+1 is the filter length. Signal wₘ(t) is additive zero mean white Gaussian noise, is the m-th element of the M×1 vector w(t), and is independent from the source signal, where wₘ(t) is defined as:

$$E [ w ( t ) \cdot {w}^{T} ( t ) ] = {σ}^{2} {I}_{M} , \qquad ( 2 )$$

where E is statistical expectation, I_{M} is an M×M identity matrix, and σ² is the noise variance.

The objective of receiver 12 is to estimate the original source signals x(t) from the measurements y(t). When the number of measurements is less than the number of sources (i.e., M<N), the problem is under-determined and an infinite number of solutions exist. These problems can be conditioned given a priori information about the sources. As discussed above, source signals x(t) are sparse in multiple domains (e.g., time and frequency domains). Thus, a compound mixing matrix models convolution in the time domain. To this end, convolutive model in Equation (1) above can be written as:

$$y = Ax + w , \qquad ( 3 )$$

where the extended measurement vector y=[y₁, . . . , y_{M}]′ and the extended noise vector w=[w₁, . . . , w_{M}]′ are the concatenation of the 1×(P−L) vectors yₘ and wₘ, respectively. The vectors yₘ and wₘ are defined respectively as follows:

$${y}_{m} = [ {y}_{m} ( P - 1 ) , ... , {y}_{m} ( L + 1 ) , {y}_{m} ( L ) ] , \qquad ( 4 )$$

$${w}_{m} = [ {w}_{m} ( P - 1 ) , ... , {w}_{m} ( L + 1 ) , {w}_{m} ( L ) ] , \qquad ( 5 )$$

where P is the frame length of each source signal and P−L is the consequent length of the portion of mixture signals yₘ, m=1, . . . , M, which are dependent on only the selected P samples of the source signals assuming FIR filters of length L. Note that [⋅]′ represents transposition.

The extended source vector x=[x₁, . . . , X_{N}]′ is also the concatenation of the 1×P vectors xₙ, for n=1, . . . , N where:

$${x}_{n} = [ {x}_{n} ( P - 1 ) , ... , {x}_{n} ( 1 ) , {x}_{n} ( 0 ) ] . \qquad ( 6 )$$

The mixing matrix A is then defined as the banded block Toeplitz matrix:

$$A = [ \begin{matrix}{A}_{11} & … & {A}_{1 N} \\ ⋮ & ⋱ & ⋮ \\ {A}_{M 1} & … & {A}_{MN}\end{matrix} ] , \qquad ( 7 )$$

$$where$$

$${A}_{mn} = [ \begin{matrix}{a}_{mn} ( 0 ) & … & {a}_{mn} ( L ) & … & 0 \\ ⋮ & ⋱ & ⋱ & ⋱ & ⋮ \\ 0 & … & {a}_{mn} ( 0 ) & … & {a}_{mn} ( L )\end{matrix} ] , ∀ m , n , \qquad ( 8 )$$

is a (P−L)×P banded Toeplitz matrix.

In CBSS, both mixing matrix A and source vector x are unknown. Source vector x could be estimated using the convolutive model in Equation (3) above. The missing matrix A has banded block Toeplitz structure with repetitive elements on the diagonals. Estimating matrix A using the convolutive model in Equation (3) is impossible since the banded block Toeplitz structure of the matrix cannot be enforced. Without this constraint, the number of unknowns is much higher than the number of channel coefficients. Therefore, using a defined regenerating matrix B, the convolutive model in Equation (1) can be written as:

$$Y = BH + W , \qquad ( 9 )$$

where the measurement matrix Y, noise matrix W, regenerating matrix B, and channel matrix H are defined as:

$$Y = [ {y}_{1}^{′} , ... , {{y}_{M}}^{′} ] , \qquad ( 10 )$$

$$W = [ {w}_{1}^{′} , ... , {{w}_{M}}^{′} ] , \qquad ( 11 )$$

$$B = [ \begin{matrix}{x}_{1} ( P - 1 ) & {x}_{1} ( P - 2 ) & … & {x}_{1} ( L ) \\ ⋮ & ⋮ & ⋮ & ⋮ \\ {x}_{1} ( P - 1 - L ) & {x}_{1} ( P - 2 - L ) & … & {x}_{1} ( 0 ) \\ ⋮ & ⋮ & ⋮ & ⋮ \\ {x}_{N} ( P - 1 ) & {x}_{N} ( P - 2 ) & … & {x}_{N} ( L ) \\ ⋮ & ⋮ & ⋮ & ⋮ \\ {x}_{N} ( P - 1 - L ) & {x}_{N} ( P - 2 - L ) & … & {x}_{N} ( 0 )\end{matrix} ] , and \qquad ( 12 )$$

$$H = [ \begin{matrix}{a}_{11} ( 0 ) & {a}_{21} ( 0 ) & … & {a}_{M 1} ( L ) \\ ⋮ & ⋮ & ⋮ & ⋮ \\ {a}_{11} ( L ) & {a}_{21} ( L ) & … & {a}_{M 1} ( L ) \\ ⋮ & ⋮ & ⋮ & ⋮ \\ {a}_{1 N} ( 0 ) & {a}_{2 N} ( 0 ) & … & {a}_{MN} ( 0 ) \\ ⋮ & ⋮ & ⋮ & ⋮ \\ {a}_{1 N} ( L ) & {a}_{2 N} ( L ) & … & {a}_{MN} ( L )\end{matrix} ] . \qquad ( 13 )$$

Based on the definition of matrices H and A, estimation of the channel matrix H is equivalent to estimation of the mixing matrix A. Therefore, receiver 12 can use the convolutive model in Equation (9) to estimate the channel matrix H (the channel coefficients).

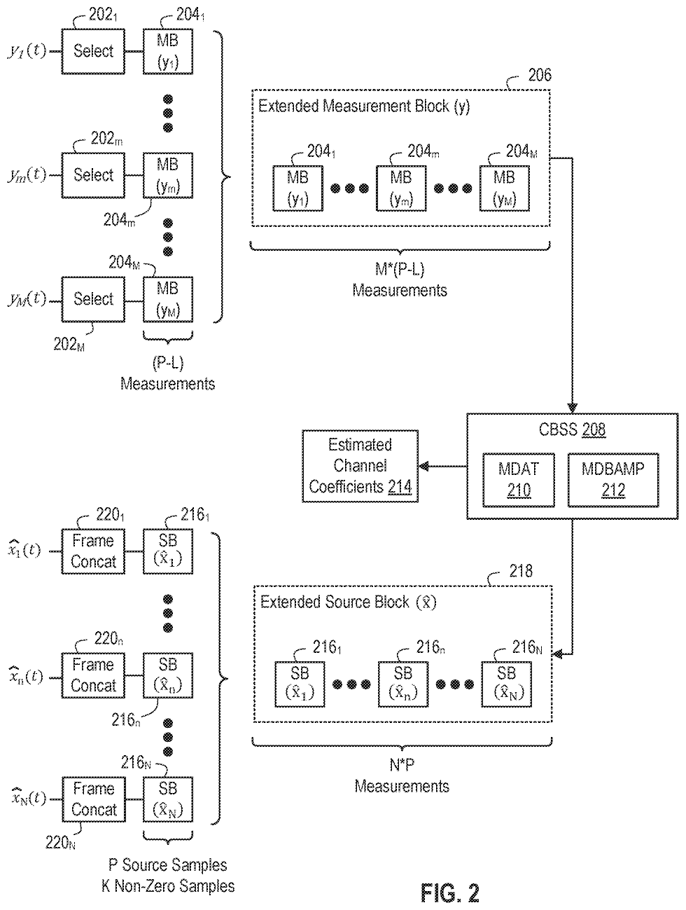

FIG. 2 is a block diagram depicting logical operation of a processor 32 in a receiver 12 of a distributed edge system 100 according to embodiments. In embodiments, processor 32 can perform functions as described herein by executing software or firmware instructions stored in a memory. Processor 32 can be a general-purpose microprocessor or a specific-purpose processor, such as digital signal processor (DSP). In other embodiments, processor 32 can perform its functions in hardware using hardware circuits. Processor 32 can be circuitry implemented by programming a programmable logic device (PLD), such as a field programmable gate array (FPGA), or by fixed circuitry in an integrated circuit (IC), such as an application specific integrated circuit (ASIC). In still other embodiments, processor 32 performs its functions using a combination of software/firmware execution and hardware circuits. For example, processor 32 can some hardware circuits in an FPGA/ASIC and a microprocessor/DSP embedded in the FPGA/ASIC configured to execute software/firmware. In some embodiments, processor 32 can be implemented on a larger IC that also includes other circuitry of receiver 12, including circuitry for sources 36 and transmitter 40.

Processor 32 receives mixed signals y(t) from sensors 36. Processor 32 includes select logic 202 that selects measurement blocks (MBs) 204 of measurements from the mixed signals y(t). Thus, processor 32 includes select logic 202₁ that selects an MB 204₁ from mixed signal y₁(t); select logic 202ₘ that selects an MB 204ₘ from mixed signal yₘ(t); and so on until select logic 202_{M} that selects an MB 204_{M} from mixed signal y_{M}(t). Each MB 204₁ . . . 204_{M} includes (P−L) mixed signal measurements, which corresponds to measurement vectors y₁ . . . y_{M} described above. Processor 32 multiplexes MB 204₁ . . . 204_{M} into an extended MB 206, which corresponds to the extended measurement vector y described above. Extended MB 206 includes M*(P−L) total mixed signal measurements.

Processor 32 implements CBSS logic 208. CBSS logic 208 receives extended MB 206 and generates estimated channel coefficients 214 and extended source block (SB) 218. In embodiments, processor 32 includes two implementations for CBSS 208, which include MDAT 210 and MDBAMP 212. Processor 32 can select between MDAT 210 and MDBAMP 212 when processing extended MB 206 to generate estimated channel coefficients 214 and extended SB 218. Embodiments of MDAT 210 and MDBAMP 212 are described below.

Extended SB 218 comprises SBs 216, namely SBs 216₁ . . . 216_{N} corresponding to frames of estimated source vectors \hat{x}₁, . . . , \hat{x}_{N}. Processor 32 demultiplexes SBs 216₁ . . . 216_{N} from extended SB 218. Each SB 216₁ . . . 216_{N} comprises P estimated source samples, including K non-zero estimated source samples (a “source frame”). Processor 32 includes frame concatenation logic 220₁ . . . 220_{N} that concatenates processed frames for each estimated source to output estimated source signals \hat{x}₁(t), . . . , \hat{x}_{N}(t), respectively. Thus, blocks of mixed signals y(t) are processed sequentially by CBSS 208 to generate estimated channel coefficients 214 and frames of estimated source signals \hat{x}(t).

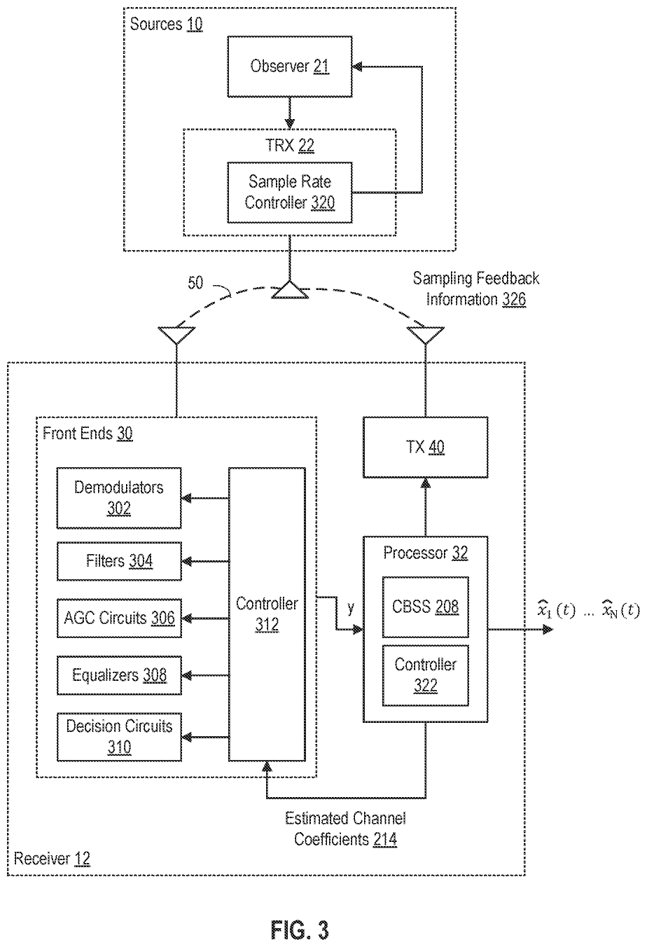

FIG. 3 is a block diagram depicting logical operation of a processor 32 in feeding back information to sources 10 and front-ends 30 in a distributed edge system 100 according to embodiments. Processor 32 includes CBSS logic 208 to generate estimated source signals \hat{x}₁(t), . . . , \hat{x}_{N}(t) and estimated channel coefficients 214. Processor 32 can include control logic (“controller 322”) configured to perform control functions of receiver 12. In embodiments, controller 322 can select the implementation of CBSS 208 (e.g., between MDAT 210 and MDBAMP 212). Controller 322 can make the selection based on whether the CBSS problem is over-determined or under-determined. As discussed further below, MDBAMP 212 does not converge for the over-determined case but exhibits increased performance over MDAT 210 in the under-determined case. Controller 322 can switch to MDAT 210 in an over-determined case and use MDAT 210 or MDBAMP 212 in an under-determined case.

Controller 322 can also provide estimated channel coefficients 214 to a controller 312 in each of FEs 30. In an FE 30, controller 312 can use estimated channel coefficients 214 to adjust how the RF signal is received and the mixed signal is generated based on changes to channel 50 indicated by changes in estimated channel coefficients 214. For example, FEs 30 can include various circuitry depending on the type of modulation employed by sources 10, including one or more of: demodulators 302, filters 304, automatic gain control (AGC) circuits 306, equalizers 308, decision circuits 310, and the like. Controller 312 can adjust one or more of such circuits based on changes to channel coefficients 214 to adapt to changes in channel 50.

Controller 322 can also determine from output of CBSS logic 208 information to control sampling rates of sources 10. For example, controller 322 can determine new sampling rates based on whether the problem is over-determined or under-determined, including based on a measure of how much the problem is under-determined (e.g., above or below a threshold for obtaining a solution). Controller 322 can determine more aggressive sampling rates (lower rates) or less aggressive rates (higher rates) depending on the over-determinedness or under-determinedness of the problem. Controller 322 can send sampling feedback information 326 to sources 10 using transmitter 40. Transceiver 22 can provide sampling feedback information 326 to a sample rate controller 320, which controls a sampling rate of observer 21.

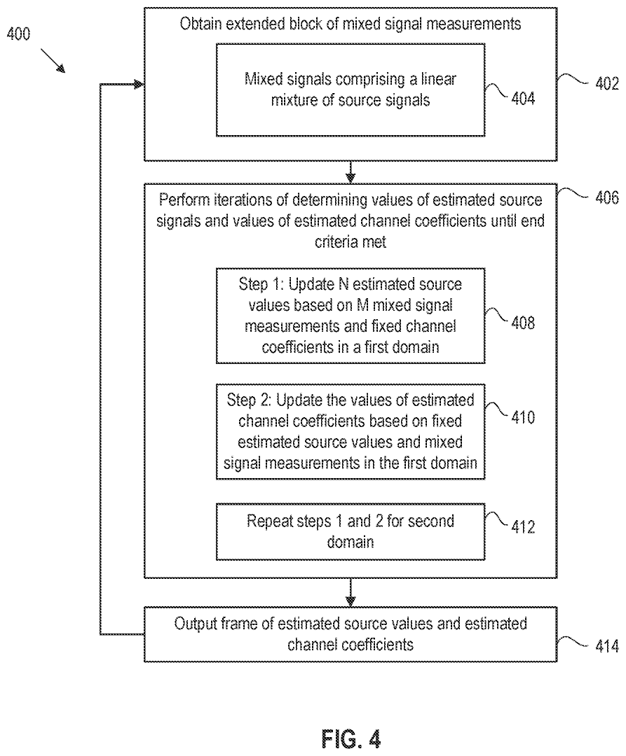

FIG. 4 is a flow diagram depicting a method 400 of estimating source signals and channel coefficients using CBSS according to embodiments. The CBSS problem is to separate the source signals while the mixing matrix is unknown. In embodiments, CBSS logic 208 performs an iterative algorithm that has two steps in each iteration. In the first step, CBSS logic 208 estimates all N source signals from M mixed signal measurements. In the second step, CBSS logic 208 estimates the channel matrix H. CBSS logic 208 can then form the mixing matrix A based on entries of the channel matrix H (the estimated channel coefficients).

In embodiments, the source signals are sparse in both time and frequency domains. Therefore, the following optimization problem is introduced based on multiple domain sparsity of the source signals:

$${min}_{x , A} λ {‖ x ‖}_{1} + ( 1 - λ ) {‖ \tilde{F} x ‖}_{1} \qquad ( 14 )$$

$$s . t . {‖ y - Ax ‖}_{2} \leq α ,$$

where \tilde{F} is the block diagonal Fourier matrix defined as:

$$\tilde{F} = [ \begin{matrix}F & & & \\ & F & & \\ & & ⋱ & \\ & & & F\end{matrix} ] \qquad ( 15 )$$

F is the P×P discrete Fourier transform (DFT) matrix and \tilde{F} is NP×NP (note that matrix elements in F other than the diagonal are 0). Parameter λ is used to adjust the contributions for each domain. Furthermore, the parameter α bounds the l₂-norm of noise is: α=σ{square root over (L_{y}+2\sqrt{2L_{y}})}

$$α = σ \sqrt{{L}_{y} + 2 \sqrt{2 {L}_{y}}} , \qquad ( 16 )$$

where L_{y}=M(P−L) is the length of measurement vector y.

Method 400 begins at step 402, where CBSS logic 208 obtains an extended block of mixed signal measurements (e.g., extended MB 206). The mixed signals comprise a linear combination of the source signals (step 404). At step 406, CBSS logic 208 perform iterations of determining values of estimated source signals and values of estimated channel coefficients until end criteria are met. For example, at step 408, a first step updates N estimated source values based on M mixed signal measurements and fixed channel coefficient values in a first domain (e.g., time domain). At step 410, a second step updates the values of estimated channel coefficients based on the fixed estimated source values and mixed signal measurements in the first domain (e.g., time domain). At step 412, steps 408 and 410 are repeated for a second domain (e.g., frequency domain or time-wavelet domain). At step 414, CBSS logic 208 outputs a frame of estimated source values and estimated channel coefficients. Method 400 can repeat for each extended block of mixed signal measurements. The frames of estimated source values are concatenated to generate the estimated source signals.

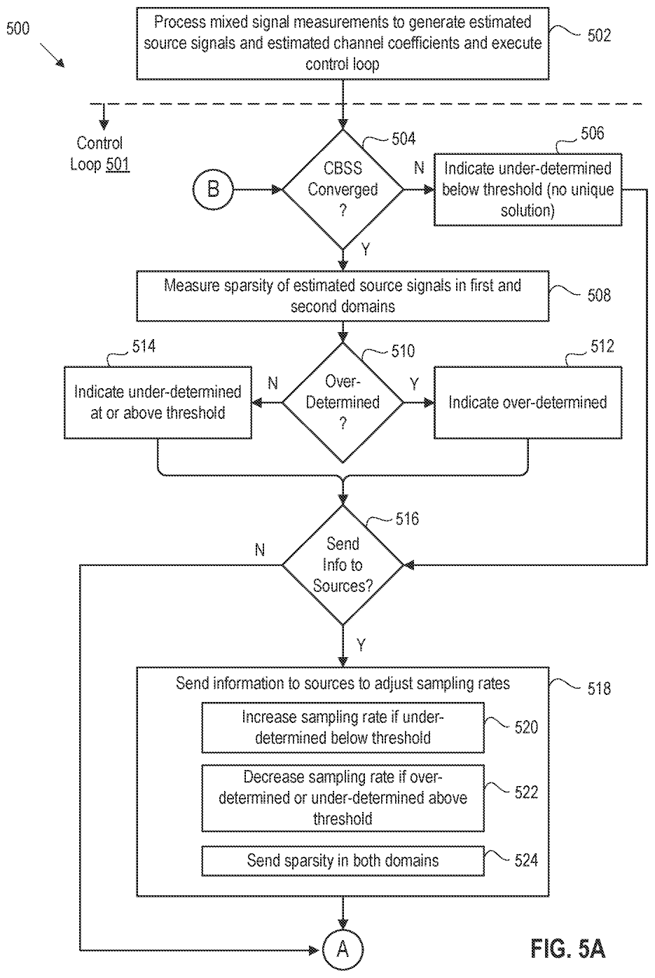

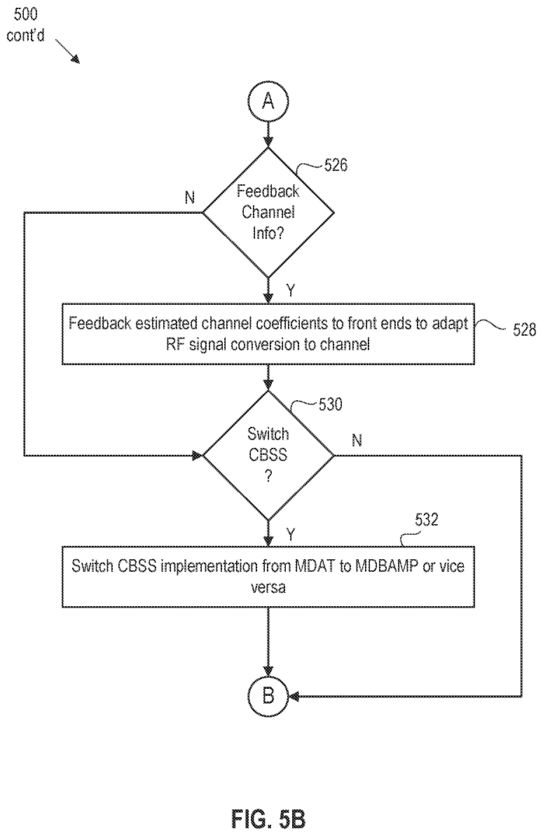

FIGS. 5A-5B depict a flow diagram showing a method 500 of controlling parameters in a distributed edge system according to embodiments. Method 500 begins a step 502, where processor 32 processes mixed signal measurements to generate estimated source signals and estimated channel coefficients and execute a control loop 501. Processor 32 executes control loop 502 as measurements are processed and estimations determined. In control loop 501, at step 504, processor 32 determines if CBSS logic 208 is converging. If not, method 500 proceeds to step 506, where processor 32 indicates that the CBSS problem is under-determined below a threshold such that there is no solution. Otherwise, method 500 proceeds to step 508. From step 506, method 500 proceeds to step 516.

As discussed above, there are both over-determined and under-determined cases for CBSS. The system is considered under-determined if there are fewer equations than unknowns. Therefore, when the mixing matrix A is known, the system is considered under-determined if the length of the mixed signal measurement vector y is smaller than the length of the estimated source vector x, i.e., M(P−L)≤NP. Similarly, when the mixing matrix A is unknown, the system is considered under-determined if M(P−L)≤NP+NML where NM(L+1) is the number of unknown channel coefficients. As a theoretical limit, estimation fails when the number of non-zero unknowns is greater than the number of equations, i.e., M(P−L). In other words, in the case of CBSS, if the source vector has K non-zero entries, we should have at least K+NM(L+1) equations, where K+NM(L+1)≤M(P−L). Since the source signals are sparse, the number of non-zero entries is smaller than the length of the source vector x and therefore there exists an under-determined case where K+NM(L+1)≤M(P−L)≤NP+NM(L+1). This inequality is the necessary condition for the under-determined system to have a unique solution.

If at step 504 CBSS is not converging, it is likely that the inequality above is not satisfied and there is no unique solution. If CBSS is converging, at step 508, processor 32 measures sparsity of the estimated source signals in the first and second domains (e.g., time and frequency domains). Processor 32 can determine a value for K and, given values for N, M, P, and L can determine values for over-determined/under-determined conditions discussed above. If CBSS is overdetermined at step 510, method 500 proceeds to step 512, where processor 32 indicates the over-determined condition. Otherwise, method 500 proceeds to step 514, where processor 32 indicates the under-determined condition at or above the threshold of no solution.

At step 516, processor 32 determines if it should send sampling rate feedback to the sources. If so, method 500 proceeds to step 518; otherwise method 500 proceeds to step 526. At step 518, processor 32 sends information to the sources to adjust the sampling rates. For example, at step 520, processor 32 can determine to increase sampling rates if CBSS is not converging (under-determined below the no solution threshold). Or at step 522, processor 32 can decrease the sampling rate if CBSS is over-determined or under-determined above the no solution threshold. Depending on the condition of the CBSS problem, processor 32 can determine a more aggressive sampling rate or a less aggressive sampling rate. As an alternative, at step 524, processor 32 can send sparsity information in both domains to the sensors and the sensors can determine how to adjust their sampling rates based on the measured sparsity information at the receiver.

At step 526, processor 32 determines if it should feedback channel information to the sensors. If not, method 500 proceeds to step 530; otherwise method 500 proceeds to step 528. At step 528, processor 32 send estimated channel coefficients to the front-ends in the sensors to adapt the RF signal conversion process to the channel. At step 530, processor 32 can determine whether to switch the CBSS implementation. If so, method 500 proceeds to step 532; otherwise method 500 returns to step 504. At step 532, processor 32 switches the CBSS implementation from MDAT to MDBAMP or vice versa. The processor 32 can switch to MDAT if the CBSS problem is over-determined, since MDBAMP does not converge in that condition. The processor 32 can switch to MDBAMP (optionally) if the CBSS problem is under-determined to achieve better performance.

As discussed above, MDAT can be used in both over-determined and under-determined conditions, while MDBAMP can be used in the under-determined condition. Regular approximate message passing (AMP) with known mixing matrix can be used for under-determined cases and it also fails to converge for over-determined cases. In both MDAT and MDBAMP, CBSS logic 208 iteratively estimates source signals for fixed mixing matrix and then estimates the mixing matrix for fixed source signals. In the blind source separation of sparse sources, where the mixing matrix is unknown, an equal multiplier of sparsity for both domains can be set. Each iteration of CBSS logic 208 includes two half iterations in which estimation is performed in a single domain. Both MDAT and MDBAMP iteratively solve Equation 14 as follows:

$$Step 1 : Estimation of x for fixed A \qquad ( 17 )$$

$${min}_{x} \qquad {‖ Dx ‖}_{1}$$

$$\begin{matrix}s . t . & {‖ y - Ax ‖}_{2} \leq α\end{matrix} ,$$

$$Step 2 : Estimation of A for fixed x \qquad ( 18 )$$

$${min}_{A} \qquad {‖ y - Ax ‖}_{2}$$

In each iteration, CBSS logic 208 repeats these two steps two times, the first time for D=I where I is the identity matrix and the second time for D=\tilde{F}. In other words, in the first half iteration, CBSS logic 208 estimates sources based on their sparsity in the time domain and in the second half iteration CBSS logic 208 estimates sources based on their sparsity in the frequency domain.

Although the decisions in control loop 501 are shown in specific sequence, processor 32 can perform the decisions concurrently or in a different sequence. In general, processor 32 can process the estimations output from CBSS logic 208 and make decisions on whether to request the sensors to adjust their sampling rates, send channel estimations to the sensors to adjust the RF signal conversion, and swap between implementations of the CBSS.

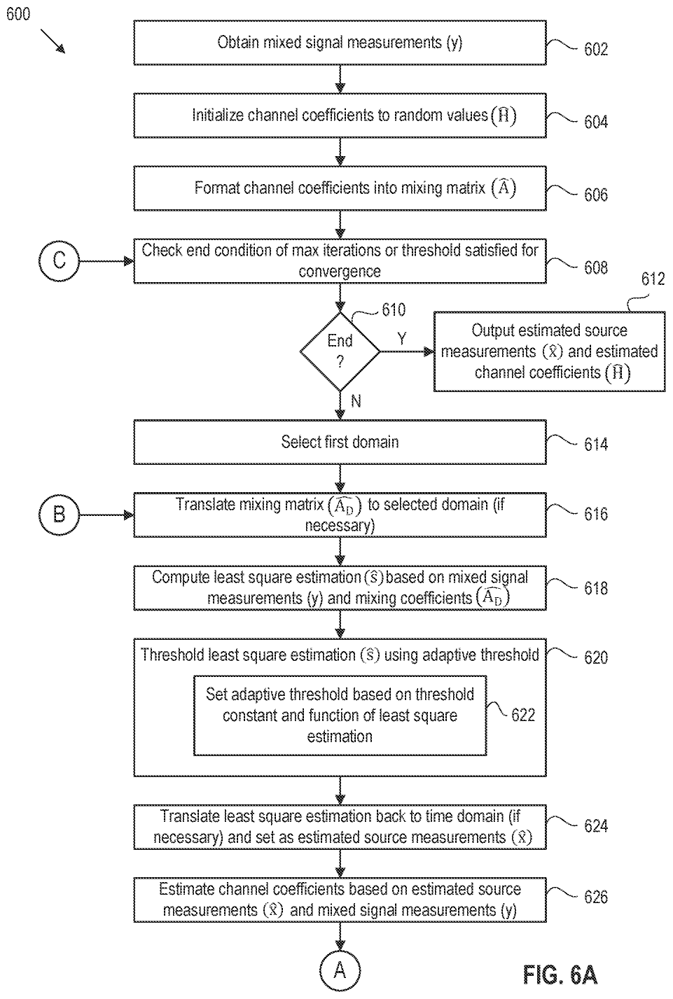

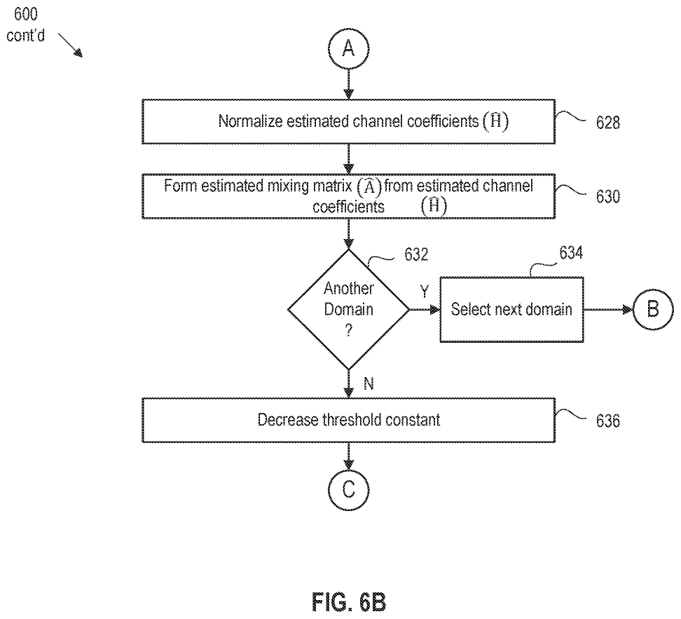

FIGS. 6A-6B depict a flow diagram showing a method 600 of multi-domain adaptive thresholding (MDAT) according to embodiments. The MDAT algorithm operates on multiple domains. Equation (3) above can be rewritten in any particular domain with a corresponding dictionary D as follows:

$$y = A {D}^{- 1} s + w , \qquad ( 19 )$$

where s=Dx.

Method 600 begins at step 602, where CBSS logic 208 obtains an extended measurement block of mixed signal measurements (extended measurement vector y). At step 604, CBSS logic 208 initializes the channel coefficients to random values. That is, CBSS logic 208 initializes an estimated channel matrix Ĥ randomly. At step 606, CBSS logic 208 formats the channel coefficients into an estimated mixing matrix. That is, CBSS logic 208 forms an estimated mixing matrix Â based on the estimated channel matrix Ĥ according to Equation (7) above.

At step 608, CBSS logic 208 checks an end condition of a logical OR between the iterations (j) reaching a maximum number of iterations (j_{MAX}) or a threshold is satisfied for convergence. Convergence can be determined based on:

$$\frac{{‖ y - \hat{A} \hat{x} ‖}_{2}}{{‖ y ‖}_{2}} \leq threshold \qquad ( 20 )$$

If at step 610 the end condition is satisfied, method 600 proceeds to step 612, where CBSS logic 208 outputs estimated source values (estimated extended source vector \hat{x}) and estimated channel coefficients (estimated channel matrix Ĥ). If at step 610 the end condition is not satisfied, method 600 proceeds to step 614.

At step 614, CBSS logic 208 selects a first domain (first dictionary D). In embodiments, the first domain comprises a time domain (dictionary D=I, the identity matrix). At step 616, CBSS logic 208 translates the estimated channel coefficients (in mixing matrix form) to the selected domain (D). When the domain is the time domain, no actual translation occurs. That is, CBSS logic 208 computes:

$${\hat{A}}_{D} = \hat{A} {D}^{- 1} . \qquad ( 21 )$$

At step 618, CBSS logic 208 computes least square estimations based on the mixed signal measurements and fixed values of the estimated channel coefficients (current values of the estimated channel coefficients in mixing matrix form). That is, CBSS logic 208 computes the following:

$$\tilde{s} = {( {{\hat{A}}^{′}}_{D} {\hat{A}}_{D} )}^{- 1} {{\hat{A}}^{′}}_{D} y , \qquad ( 22 )$$

where \tilde{s} is a vector of the least square estimations.

At step 620, CBSS logic 208 thresholds the least square estimations using an adaptive threshold. In an embodiment, CBSS logic 208 computes f(\tilde{s}), where the function f computes the mean absolute deviation of the values in least square estimations vector (a scalar value). The adaptive threshold in the current domain D (δ_{D}) can be defined as:

$${δ}_{D} = {κ}_{D} f ( \tilde{s} ) , \qquad ( 23 )$$

where κ_{D} is a constant that decreases from iteration to iteration. The initial values of κ_{I} in the time domain and κ_{\tilde{F}} in the frequency domain can be different. A vector of least square estimations after thresholding (Ŝ) is computed by:

$$\hat{s} = {ℋ}_{{δ}_{D}} ( \tilde{s} ) , \qquad ( 24 )$$

where [symbol] _{δ}_{_{D}} is the thresholding operator. Without loss of generality, the thresholding operator can be defined as:

$${ℋ}_{{δ}_{D}} ( {\tilde{s}}_{i} ) = \{ \begin{matrix}{\tilde{s}}_{i} & if \vert {\tilde{s}}_{i} \vert > {δ}_{D} , \\ 0 & otherwise .\end{matrix} \qquad ( 25 )$$

Thus, at step 622, CBSS logic 208 sets the adaptive threshold based on a threshold constant (κ_{D}) and a function of the least square estimation vector (f(\tilde{s})).

At step 624, CBSS logic 208 translates the thresholded least square estimations (Ŝ) back to the time domain if necessary. If the thresholded least square estimations are already in the time domain, no translation is occurs. CBSS logic 208 sets the values of the estimated source signals to the thresholded least square estimations. That is, CBSS logic 208 computes:

$$\hat{x} = {D}^{- 1} \hat{s} . \qquad ( 26 )$$

At step 626, CBSS logic 208 estimates the channel coefficients based on the estimated source values (\hat{x}) and the mixed signal measurements (y). CBSS logic 208 forms an estimated regenerating matrix \hat{B} based on Equation (12) above using the estimated source values (\hat{x}). CBSS logic 208 then computes the estimated channel matrix Ĥ as follows:

$$\hat{H} = {( {\hat{B}}^{′} \hat{B} )}^{- 1} {\hat{B}}^{′} Y , \qquad ( 27 )$$

where columns of the matrix Y are the mixed signal measurement vectors y₁ . . . y_{M}.

At step 628, CBSS logic 208 normalizes the estimated channel coefficients (all columns of Ĥ. At step 630, CBSS logic 208 forms the estimated mixing matrix (Â) from the estimated channel coefficients (Ĥ). At step 632, CBSS logic 208 determines whether there is another domain to process. If so, method 600 proceeds to step 634 and selects the next domain. If domain is currently the time domain (D=I), then the domain is set to the frequency domain (D=\tilde{F}). From step 634, method 600 returns to step 616. If at step 632 the domain is currently the frequency domain, then there is no other domain to process and method 600 proceeds from step 632 to step 636. At step 636, CBSS logic 632 decreases the threshold constant for each domain (κ_{I} and κ_{\tilde{F}}). Method 600 then returns to step 608 to check the end condition.

MDAT is an iterative algorithm such that at each iteration it computes sparse sources in both time and frequency domains. Due to the joint-domain sparsity, each iteration includes two half iterations as discussed above. In the first half iteration, MDAT estimates the source signals based on their sparsity in the time domain and then estimates the channel coefficients. In the second half iteration, MDAT estimates the source signals based on their sparsity in the frequency domain and then estimates the channel coefficients. Each iteration of MDAT refines the values of the estimated sources and the estimated channel coefficients. In some embodiments, instead of joint time and frequency domain estimations, MDAT can also use joint time and wavelet domain estimations. The complexity is reduced in such an embodiment, since wavelet coefficients are real numbers in contrast to complex-valued Fourier coefficients.

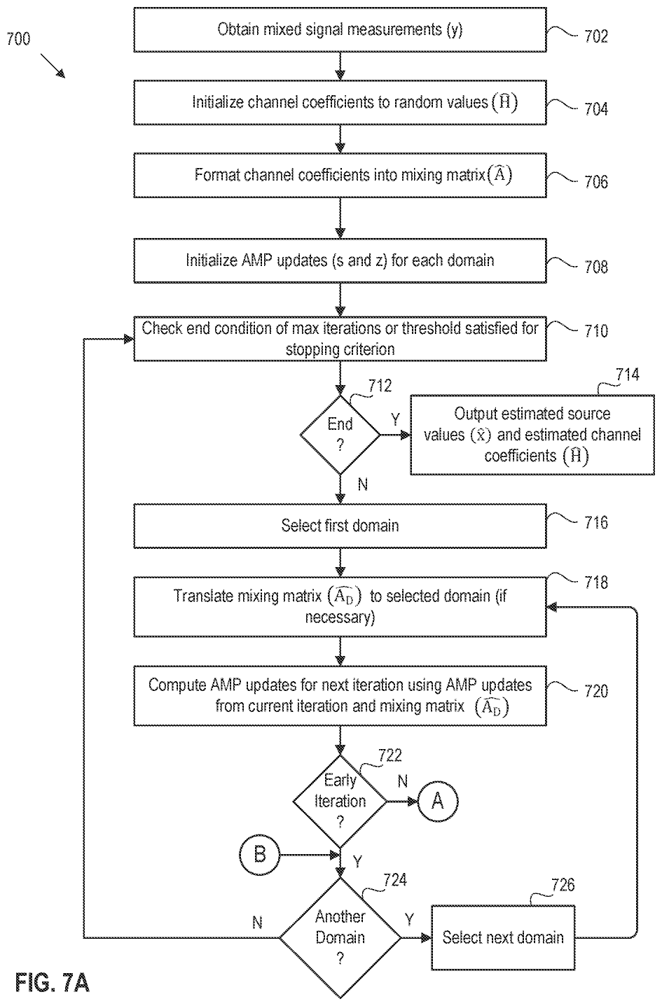

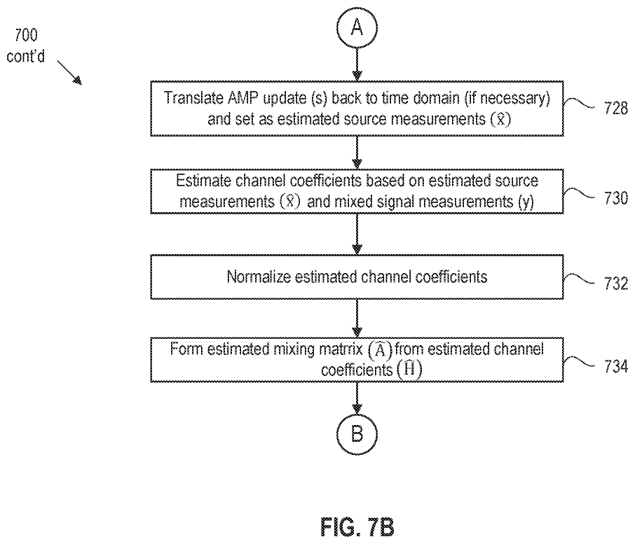

FIGS. 7A-7B depict a flow diagram showing a method 700 of multi-domain blind adaptive message passing (MDBAMP) according to embodiments. MDBAMP is an alternative to the well-known AMP algorithm when the mixing matrix A is unknown. Further, MDBAMP is performed jointly on multiple domains as opposed to AMP. In existing AMP algorithms, it is supposed that the mixing matrix A is known and only the source signals x are estimated. In MDBAMP, the mixing matrix A is unknown and both x and A are estimated. Furthermore, AMP finds the solution of [symbol] ₁ minimization while MDBAMP finds the joint domain sparse solution of a convex problem. As an introduction, the AMP algorithm is briefly explained.

AMP is an iterative algorithm to recover sparse signals such that its solution coincides with the solution of [symbol] ₁ minimization, while having less computational complexity than existing methods for such [symbol] ₁ minimization. Given a measurement vector y and a sensing matrix Á, AMP starts from s⁰=0 and solves iteratively the following equations:

$${v}^{j} = {s}^{j} + {Á}^{T} {z}^{j} , \qquad ( 28 )$$

$${s}^{j + 1} = η ( {v}^{j} ) , \qquad ( 29 )$$

$${z}^{j + 1} = y - {Ás}^{j + 1} + \frac{1}{n} div η ( {v}^{j} ) {z}^{j} , \qquad ( 30 )$$

until a stopping criterion is met, where s^{j} is the estimate of s in the j-th iteration, z^{j} is the residual vector, η(⋅): [symbol] ₙ→ [symbol] ₙ is a threshold function and “div” denotes a divergence operator.

The threshold function η(⋅) plays an important role on the performance of AMP. The solution of [symbol] ₁-norm minimization coincides with that of AMP when η(⋅) is a soft threshold function. In soft thresholding, the i-th element of ηᵢ^{ST}(x), i.e., ηᵢ^{ST} is given by:

$${η}_{i}^{S T} = ( 1 - \frac{τ}{\vert {x}_{i} \vert} ) {x}_{i} , ∀ i = \{ 1 , … , N \} . \qquad ( 31 )$$

MDBAMP is an iterative algorithm to estimate jointly sparse sources in CBSS. As with the MDAT algorithm, each iteration of MDBAMP includes two half iterations. In each half iteration, the part relating to the estimation of the channel coefficients remains unchanged while the part relating to the estimation of the sources is substituted with each of time or frequency domain AMP. Similar to MDAT, a time-wavelet dictionary can replace the Fourier dictionary in the second domain to reduce complexity.

Method 700 begins at step 702, where CBSS logic 208 obtains an extended measurement block of mixed signal measurements (extended measurement vector y). At step 704, CBSS logic 208 initializes the channel coefficients to random values. That is, CBSS logic 208 initializes an estimated channel matrix Ĥ randomly. At step 706, CBSS logic 208 formats the channel coefficients into an estimated mixing matrix. That is, CBSS logic 208 forms an estimated mixing matrix Â based on the estimated channel matrix Ĥ according to Equation (7) above. At step 708, CBSS logic 208 initializes the AMP updates (s and z) for each domain. Assume for the first iteration, j=0. Then s_{I}^{j}=0 and z_{I}^{j}=y in the time domain and s_{\tilde{F}}^{j}=0 and z_{\tilde{F}}^{j}=y in the frequency domain.

At step 710, CBSS logic 208 checks an end condition of a logical OR between the iterations (j) reaching a maximum number of iterations (j_{MAX}) or a threshold is satisfied for convergence. The convergence threshold can be as described above in Equation (20). If at step 712 the end condition is satisfied, method 700 proceeds to step 714, where CBSS logic 208 outputs estimated source values (estimated extended source vector \hat{x}) and estimated channel coefficients (estimated channel matrix Ĥ). If at step 712 the end condition is not satisfied, method 700 proceeds to step 716.

At step 716, CBSS logic 208 selects a first domain (first dictionary D). In embodiments, the first domain comprises a time domain (dictionary D=I, the identity matrix). At step 718, CBSS logic 208 translates the estimated channel coefficients (in mixing matrix form) to the selected domain (D) using Equation (21). When the domain is the time domain, no actual translation occurs.

At step 720, CBSS logic 208 computes AMP updates for the next iteration (j+1) using the AMP updates from the current iteration (j) and the channel coefficients (in mixing matrix form). CBSS logic 208 computes the AMP updates as follows:

$${v}_{D}^{j} = {s}_{D}^{j} + {\hat{A}}_{D}^{T} {z}_{D}^{j} , \qquad ( 32 )$$

$${s}_{D}^{j + 1} = {η}^{S T} ( {v}_{D}^{j} , τ ) , \qquad ( 33 )$$

$${b}_{j + 1} = \frac{1}{N P} div {η}^{S T} ( {v}_{D}^{j} , τ ) , \qquad ( 34 )$$

$${z}_{D}^{j + 1} = y - {\hat{A}}_{D} {s}_{D}^{j + 1} + {b}_{j + 1} {z}_{D}^{j} , \qquad ( 35 )$$

where τ is the M(P−L)-th largest element of |v_{D}^{j}|.

At step 722, CBSS logic 208 determines if the iteration is an early iteration. If so, method 700 proceeds to step 724. At step 724, CBSS logic 208 determines whether there is another domain to process. If so, method 700 proceeds to step 726 and selects the next domain. If domain is currently the time domain (D=I), then the domain is set to the frequency domain (D=\tilde{F}). From step 726, method 700 returns to step 718. If at step 724 the domain is currently the frequency domain, then there is no other domain to process and method 700 proceeds from step 724 to step 710 to check the end condition.

If at step 722 CBSS logic 208 determines the iteration is not an early iteration, method 700 proceeds to step 728. In the MDBAMP algorithm, for the first j₁ iterations, the channel coefficients are not estimated. In the AMP algorithm for the case of a known mixing matrix, estimation of the sources in the early iterations are far from the final estimations and some iterations are needed to approach the final estimation. In MDBAMP, as the modified version of AMP, only source estimation is determined for the first j₁ iterations (early iterations). Thereafter, MDBAMP also estimates the channel coefficients (after the early iterations).

At step 728, CBSS logic 208 translates the AMP update (s_{D}^{j}) back to the time domain if necessary. If such AMP update is already in the time domain, no translation is occurs. CBSS logic 208 sets the values of the estimated source signals to the AMP update (s_{D}^{j}). That is, CBSS logic 208 computes:

$${x}^{j} = {D}^{- 1} {s}_{D}^{j} . \qquad ( 36 )$$

At step 730, CBSS logic 208 estimates the channel coefficients based on the estimated source values (x^{j}) and the mixed signal measurements (y). CBSS logic 208 forms an estimated regenerating matrix \hat{B} based on Equation (12) above using the estimated source values (x^{j}). CBSS logic 208 then computes the estimated channel matrix Ĥ as in Equation (27). At step 732, CBSS logic 208 normalizes the estimated channel coefficients (all columns of Ĥ). At step 734, CBSS logic 208 forms the estimated mixing matrix (Â) from the estimated channel coefficients (Ĥ). Method 700 proceeds to step 724 from step 734.

Distributed compressive sensing of multi-domain sparse signals in distributed edge systems has been described. In embodiments, a receiver in a distributed edge system comprises sensors configured to receive RF signals from a channel in an environment. The sensors include front-end circuits configured to convert the RF signals into mixed signals at baseband having a discrete-time basis, each of the mixed signals comprising a mixture of source signals, which are compressively sampled and transmitted by sources in the distributed edge system over the channel. The receiver includes a processor, coupled to the sensors, configured to use measurements of the mixed signals with an implementation of CBSS in multiple domains to separate estimated source signals from the mixed signals and determine estimated channel coefficients for the channels. The processor is configured to send, to the sources, information to adjust sampling rates in response to a relation between the measurements, the estimated source signals, and the estimated channel coefficients.

The techniques described herein improve the function of hardware in the distributed edge system. The MDAP and MDBAMP implementations of CBSS generate estimated channel coefficients, which can be used by front-end circuits in the receiver to adjust how the RF signals are received from the channel as the channel changes over time. The results of the MDAP and MDBAMP implementations of the CBSS also provide information for determining the condition of the CBSS process (i.e., over-determined or under-determined) and adjust the sampling rates at the sources to be more aggressive, thereby reducing power consumption, or less aggressive, thereby allowing the source signals to be recovered given the current channel. The techniques also improve the receiver itself, allowing for selectin of MDAP or MDBAMP depending on the condition of the CBSS process (allowing for convergence given an over-determined condition or allowing for improved performance given an under-determined condition).

While some processes and methods having various operations have been described, one or more embodiments also relate to a device or an apparatus for performing these operations. The apparatus may be specially constructed for required purposes, or the apparatus may be a general-purpose computer selectively activated or configured by a computer program stored in the computer. Various general-purpose machines may be used with computer programs written in accordance with the teachings herein, or it may be more convenient to construct a more specialized apparatus to perform the required operations.

One or more embodiments of the present invention may be implemented as one or more computer programs or as one or more computer program modules embodied in computer readable media. The term computer readable medium refers to any data storage device that can store data which can thereafter be input to a computer system. Computer readable media may be based on any existing or subsequently developed technology that embodies computer programs in a manner that enables a computer to read the programs. Examples of computer readable media are hard drives, NAS systems, read-only memory (ROM), RAM, compact disks (CDs), digital versatile disks (DVDs), magnetic tapes, and other optical and non-optical data storage devices. A computer readable medium can also be distributed over a network-coupled computer system so that the computer readable code is stored and executed in a distributed fashion.

Although one or more embodiments of the present invention have been described in some detail for clarity of understanding, certain changes may be made within the scope of the claims. Accordingly, the described embodiments are to be considered as illustrative and not restrictive, and the scope of the claims is not to be limited to details given herein but may be modified within the scope and equivalents of the claims. In the claims, elements and/or steps do not imply any particular order of operation unless explicitly stated in the claims.

Boundaries between components, operations, and data stores are somewhat arbitrary, and particular operations are illustrated in the context of specific illustrative configurations. Other allocations of functionality are envisioned and may fall within the scope of the invention. In general, structures and functionalities presented as separate components in exemplary configurations may be implemented as a combined structure or component. Similarly, structures and functionalities presented as a single component may be implemented as separate components. These and other variations, additions, and improvements may fall within the scope of the appended claims.

What is claimed is:

1. A receiver in a distributed edge system, comprising:
sensors configured to receive radio frequency (RF) signals from a channel in an environment, the sensors including front-end circuits configured to convert the RF signals into mixed signals at baseband having a discrete-time basis, each of the mixed signals comprising a mixture of source signals, which are compressively sampled and transmitted by sources in the distributed edge system over the channel; and
a processor, coupled to the sensors, configured to:
use measurements of the mixed signals with an implementation of convolutive blind source separation (CBSS) in multiple domains to separate estimated source signals from the mixed signals and determine estimated channel coefficients for the channels;
send, to the sources, information to adjust sampling rates in response to a relation between the measurements, the estimated source signals, and the estimated channel coefficients.

2. The receiver of claim 1, wherein the multiple domains include a time domain and one of a frequency domain or a wavelet domain.

3. The receiver of claim 1, wherein the processor is configured to feed back the estimated channel coefficients to the front-end circuits to adapt conversion of the RF signals to the mixed signals.

4. The receiver of claim 3, wherein the front-end circuits are configured to use the estimated channel coefficients to adapt at least one of: automatic gain control (AGC) circuits, equalizers, filters, demodulators, and decision circuits.

5. The receiver of claim 1, wherein the implementation of the CBSS comprises the processor configured to:
estimate values of the estimated source signals and values of the estimated channel coefficients over a plurality of iterations until convergence;
wherein for each of the plurality of iterations the processor is configured to:
set a domain to a first domain;
update, in the domain, the values of the estimated source signals from the measurements and the values of the estimated channel coefficients;
update, in the domain, the values of the estimated channel coefficients from the values of the estimated source signals and the measurements; and
repeat the updates after changing the domain to a second domain.

6. The receiver of claim 1, wherein the implementation of the CBSS comprises multi-domain adaptive thresholding (MDAT).

7. The receiver of claim 1, wherein the implementation of the CBSS comprises multi-domain blind approximate message passing (MDBAMP).

8. A method of receiving in a distributed edge system, the distributed edge system comprising sources that compressively sample and transmit source signals over a channel to a receiver, the method comprising:
receiving, at the receiver, radio frequency (RF) signals from the channel in an environment;
converting, using front-end circuits of the receiver, the RF signals into mixed signals at baseband having a discrete-time basis, each of the mixed signals comprising a mixture of the source signals;
executing, at a processor of the receiver, an implementation of convolutive blind source separation (CBSS) in multiple domains using measurements of the mixed signals as input to separate estimated source signals from the mixed signals and determine estimated channel coefficients for the channels; and
sending, from the receiver to the sources, information to adjust sampling rates in response to a relation between the measurements, the estimated source signals, and the estimated channel coefficients.

9. The method of claim 8, wherein the multiple domains include a time domain and one of a frequency domain or a wavelet domain.

10. The method of claim 8, further comprising:
feeding back the estimated channel coefficients from the processor to the front-end circuits to adapt conversion of the RF signals to the mixed signals.

11. The method of claim 8, wherein the step of sending comprising:
determining, by the processor, that the relation is over-determined or under-determined above a threshold;
wherein the information is configured to reduce the sampling rates of the sources.

12. The method of claim 8, wherein the step of sending comprises:
determining, by the processor, that the relation is under-determined below a threshold of convergence;
wherein the information is configured to increase the sampling rates of the sources.

13. The method of claim 8, wherein the information includes sparsity values in each of the multiple domains as determined from the relation.

14. The method of claim 8, further comprising:
determining, by the processor, that the relation is under-determined above a threshold; and
switching, by the processor, the implementation of the CBSS from multi-domain adaptive thresholding (MDAT) to multi-domain blind approximate message passing (MDBAMP).

15. The method of claim 8, wherein the step of executing comprises:
estimating, by the processor, values of the estimated source signals and values of the estimated channel coefficients over a plurality of iterations until convergence, each of the plurality of iterations comprising:
setting a domain to a first domain;
updating, in the domain, the values of the estimated source signals from the measurements and the values of the estimated channel coefficients;
updating, in the domain, the values of the estimated channel coefficients from the values of the estimated source signals and the measurements; and
repeating the steps of updating after changing the domain to a second domain.

16. A distributed edge system, comprising:
sources disposed in an environment, the sources configured to compressively sample and transmit source signals; and
a receiver disposed in the environment, the receiver comprising:
sensors configured to receive radio frequency (RF) signals from a channel in the environment, the sensors including front-end circuits configured to convert the RF signals into mixed signals at baseband having a discrete-time basis, each of the mixed signals comprising a mixture of the source signals; and
a processor, coupled to the sensors, configured to: use measurements of the mixed signals with an implementation of convolutive blind source separation (CBSS) in multiple domains to separate estimated source signals from the mixed signals and determine estimated channel coefficients for the channels; and send, to the sources, information to adjust sampling rates in response to a relation between the measurements, the estimated source signals, and the estimated channel coefficients.

17. The distributed edge system of claim 16, wherein the multiple domains include a time domain and one of a frequency domain or a wavelet domain.

18. The distributed edge system of claim 16, wherein the processor is configured to feed back the estimated channel coefficients to the front-end circuits to adapt conversion of the RF signals to the mixed signals.

19. The distributed edge system of claim 16, wherein the implementation of the CBSS comprises multi-domain adaptive thresholding (MDAT).

20. The distributed edge system of claim 16, wherein the implementation of the CBSS comprises multi-domain blind approximate message passing (MDBAMP).
